(19) United States
(12) Patent Application Publication
(10) Pub. No.: US 2024/0136369 A1
(43) Pub. Date: Apr. 25, 2024

(54) DISPLAY PANEL, DEFECT CORRECTION METHOD FOR DISPLAY PANEL, AND MANUFACTURING METHOD FOR DISPLAY PANEL

(71) Applicant: Sharp Display Technology Corporation, Kameyama City (JP)

(72) Inventors: Hidetoshi NAKAGAWA, Kameyama City (JP); Yoshihisa TAKAHASHI, Kameyama City (JP); Masahiro MATSUDA, Kameyama City (JP)

(21) Appl. No.: 18/373,893

(22) Filed: Sep. 26, 2023

(30) Foreign Application Priority Data
Oct. 19, 2022 (JP) 2022-168440

(51) Int. Cl. H01L 27/12; G02F 1/1362; G02F 1/1368; G09G 3/36

(52) U.S. Cl. CPC H01L 27/1255; G02F 1/136259; G02F 1/1368; G09G 3/3674; G09G 2300/0413; G09G 2310/0286

(57) ABSTRACT

A display panel includes a display region defined by a plurality of pixels P and a peripheral region other than the display region. The display panel includes a gate drive circuit and a dummy capacitance portion in the peripheral region. The gate drive circuit includes a shift register. The dummy capacitance portion includes a plurality of capacitance elements connected in parallel and connected to a dummy stage. Each of the plurality of capacitance elements includes a first capacitance electrode, a second capacitance electrode, and a dielectric layer positioned between the first capacitance electrode and the second capacitance electrode. The dummy capacitance portion further includes at least one first connection portion with two ends respectively connected to the first capacitance electrode of any one of the plurality of capacitance elements and to the first capacitance electrode of any other one of the plurality of capacitance elements.

### CROSS-REFERENCE TO RELATED APPLICATIONS

This application claims the benefit of priority to Japanese Patent Application Number 2022-168440 filed on Oct. 20, 2022. The entire contents of the above-identified application are hereby incorporated by reference.

### BACKGROUND

### Technical Field

The disclosure relates to a display panel, a defect correction method for a display panel, and a manufacturing method for a display panel.

An active matrix display panel including a thin film transistor (TFT) is used in display devices for various applications, such as mobile terminal and television applications.

Frame narrowing of an active matrix display panel is required from the viewpoint of reducing manufacturing costs and from the viewpoint of designability and functionality. By using a gate driver monolithic (GDM) technique in which a gate drive circuit (also referred to as a “gate driver”) is integrally formed on a TFT substrate, it is possible to reduce the cost for driver mounting and narrow the frame as compared to a case in which the gate drive circuit is mounted on the TFT substrate using chip on film (COF), chip on glass (COG), or the like. This GDM technique is sometimes referred to as gate on array (GOA). For example, WO 2011/104945 discloses a display device to which the GDM technique is applied.

The gate drive circuit includes a shift register including a plurality of stages corresponding to a plurality of pixel rows included in the display device. An output of each stage of the shift register is connected to a gate bus line (scanning wiring line) associated with each pixel row, and a scanning signal is supplied to the gate bus line. To improve an operation stability of the shift register, a dummy stage which does not contribute to display is sometimes further provided, and a dummy scanning line having the same wiring line resistance as that of the gate bus line is connected to the dummy stage (for example, JP 2002-214643 and US 2007/001,987).

### SUMMARY

Improvement of the manufacturing yield of a display device to which a GDM technique is applied is in demand. An object of the disclosure is to provide a display panel capable of suppressing a decrease in manufacturing yield, a defect correction method for such a display panel, and a manufacturing method for a display panel that uses the defect correction method.

According to embodiments of the disclosure, solutions described in the following items are provided.

### Item 1

A display panel includes a plurality of pixels arrayed in a matrix shape including a plurality of pixel rows and a plurality of pixel columns, a display region defined by the plurality of pixels, a peripheral region other than the display region, a gate drive circuit provided in the peripheral region and including a shift register including a plurality of stages and a dummy stage, the plurality of stages being respectively associated with the plurality of pixel rows, and a dummy capacitance portion provided in the peripheral region. The dummy capacitance portion includes a plurality of capacitance elements connected in parallel and connected to the dummy stage. Each of the plurality of capacitance elements includes a first capacitance electrode, a second capacitance electrode, and a dielectric layer positioned between the first capacitance electrode and the second capacitance electrode. The dummy capacitance portion further includes at least one first connection portion with two ends respectively connected to the first capacitance electrode of any one of the plurality of capacitance elements and to the first capacitance electrode of any other one of the plurality of capacitance elements.

### Item 2

In the display panel according to item 1, the dummy capacitance portion includes, for each of the first capacitance electrodes of the plurality of capacitance elements, two or more electrically conductive paths each extending from an input end to each of the first capacitance electrodes of the plurality of capacitance elements, the input end being configured to input a signal for applying a potential to the first capacitance electrode.

### Item 3

In the display panel according to item 1 or 2, the at least one first connection portion includes a plurality of first connection portions, the first capacitance electrode of each of the plurality of capacitance elements is connected to one end of each of any two or more of the plurality of first connection portions, and the other end of each of the any two or more of the plurality of first connection portions is connected to the first capacitance electrode of a different capacitance element among the plurality of capacitance elements, and the plurality of capacitance elements include two or more capacitance elements each including the first capacitance electrode connected to an input end without passing through the first capacitance electrode of any of the plurality of capacitance elements, the input end being configured to input a signal for applying a potential to the first capacitance electrode.

### Item 4

In the display panel according to any one of items 1 to 3, the second capacitance electrode is provided in common to the plurality of capacitance elements and includes at least one first opening overlapping the at least one first connection portion.

### Item 5

In the display panel according to any one of items 1 to 3, the dummy capacitance portion further includes at least one second connection portion with two ends respectively connected to the second capacitance electrode of any one of the plurality of capacitance elements and to the second capacitance electrode of any other one of the plurality of capacitance elements.

### Item 6

In the display panel according to item 5, the at least one second connection portion does not overlap the at least one first connection portion.

### Item 7

In the display panel according to item 5 or 6, the dummy capacitance portion includes, for each of the second capacitance electrodes of the plurality of capacitance elements, two or more electrically conductive paths each extending from an input end to each of the second capacitance electrodes of the plurality of capacitance elements, the input end being configured to input a signal for applying a potential to the second capacitance electrode.

### Item 8

In the display panel according to any one of items 5 to 7, the at least one second connection portion includes a plurality of second connection portions, the second capacitance electrode of each of the plurality of capacitance elements is connected to one end of each of any two or more of the plurality of second connection portions, and the other end of each of the any two or more of the plurality of second connection portions is connected to the second capacitance electrode of a different capacitance element among the plurality of capacitance elements, and the plurality of capacitance elements include two or more capacitance elements each including the second capacitance electrode connected to an input end without passing through the second capacitance electrode of any of the plurality of capacitance elements, the input end being configured to input a signal for applying a potential to the second capacitance electrode.

### Item 9

In the display panel according to any one of items 5 to 8, the dummy capacitance portion further includes a conductive layer facing each of the first capacitance electrodes of the plurality of capacitance elements with an insulating layer interposed therebetween, positioned on a side of the first capacitance electrodes opposite to the second capacitance electrodes, and electrically connected to the first capacitance electrodes. The conductive layer includes at least one second opening overlapping the at least one first connection portion and the at least one second connection portion.

### Item 10

In the display panel according to item 9, the conductive layer is formed of a transparent conductive material.

### Item 11

In the display panel according to item 9 or 10, the conductive layer is formed of the same conductive film as the pixel electrode provided to each of the plurality of pixels.

### Item 12

In the display panel according to any one of items 1 to 11, the first capacitance electrode is supplied with one signal among a signal for applying a low-level potential and a scanning signal for selecting any one of the plurality of pixel rows, and the second capacitance electrode is supplied with the other signal among the signal for applying a low-level potential and the scanning signal for selecting any one of the plurality of pixel rows.

### Item 13

The display panel according to any one of items 1 to 12 includes a substrate, a gate metal layer supported by the substrate, the dielectric layer covering the gate metal layer, and a source metal layer formed on the dielectric layer. Each of the first capacitance electrodes is included in one layer among the gate metal layer and the source metal layer, and each of the second capacitance electrodes is included in the other layer among the gate metal layer and the source metal layer.

### Item 14

A defect correction method for the display panel according to any one of items 1 to 13 includes, when a dielectric breakdown occurs in any one of the plurality of capacitance elements, disconnecting the first connection portion connected at one end to the first capacitance electrode of the capacitance element where the dielectric breakdown occurred.

### Item 15

A defect correction method for the display panel according to item 4 includes, when a dielectric breakdown occurs in any one of the plurality of capacitance elements, disconnecting a portion of the first connection portion connected at one end to the first capacitance electrode of the capacitance element where the dielectric breakdown occurred, the portion overlapping the first opening.

### Item 16

A defect correction method for the display panel according to anyone of item 5 to 8 includes, when a dielectric breakdown occurs in any one of the plurality of capacitance elements, disconnecting the first connection portion connected at one end to the first capacitance electrode of the capacitance element where the dielectric breakdown occurred, or disconnecting the second connection portion connected at one end to the second capacitance electrode of the capacitance element where the dielectric breakdown occurred.

### Item 17

A defect correction method for the display panel according to anyone of items 5 to 8 includes, when a dielectric breakdown occurs in any two of the plurality of capacitance elements, disconnecting the first connection portion connected at one end to the first capacitance electrode of one of the two capacitance elements where the dielectric breakdown occurred, and disconnecting the second connection portion connected at one end to the second capacitance electrode of the other of the two capacitance elements where the dielectric breakdown occurred.

### Item 18

A defect correction method for the display panel according to any one of items 9 to 11 includes, when a dielectric breakdown occurs in any one of the plurality of capacitance elements, disconnecting the first connection portion connected at one end to the first capacitance electrode of the capacitance element where the dielectric breakdown occurred.

### Item 19

A manufacturing method for a display panel includes correcting a defect of the display panel by the defect correction method according to any one of items 14 to 18.

According to an embodiment of the disclosure, a display panel that suppresses a decrease in manufacturing yield, a defect correction method for such a display panel, and a manufacturing method for a display panel that uses the defect correction method are provided.

### BRIEF DESCRIPTION OF DRAWINGS

The disclosure will be described with reference to the accompanying drawings, wherein like numbers reference like elements.

FIG. 1 is a schematic diagram illustrating a configuration of a display device 1100a including a display panel 1000a according to a first embodiment of the disclosure.

FIG. 2 is a schematic plan view of the display device 1100a.

FIG. 3 is a schematic plan view of the display panel 1000a, and is a plan view schematically illustrating a peripheral region NA of the display panel 1000a.

FIG. 4A is a schematic plan view of the display panel 1000a, and is a plan view schematically illustrating a portion of the peripheral region NA of the display panel 1000a.

FIG. 4B is a schematic plan view for explaining an example of a defect correction method for the display panel 1000a, and is a plan view schematically illustrating a portion of the peripheral region NA of the display panel 1000a.

FIG. 5A is a schematic plan view of a display panel 1000b according to a second embodiment of the disclosure, and is a plan view schematically illustrating a portion of a peripheral region NA of the display panel 1000b.

FIG. 5B is a schematic plan view for explaining an example of a defect correction method for the display panel 1000b, and is a plan view schematically illustrating a portion of the peripheral region NA of the display panel 1000b.

FIG. 5C is a schematic plan view for explaining another example of the defect correction method for the display panel 1000b, and is a plan view schematically illustrating a portion of the peripheral region NA of the display panel 1000b.

FIG. 5D is a schematic plan view for explaining yet another example of the defect correction method for the display panel 1000b, and is a plan view schematically illustrating a portion of the peripheral region NA of the display panel 1000b.

FIG. 6A is a schematic plan view of a display panel 1000b1 according to a modified example of the second embodiment of the disclosure, and is a plan view schematically illustrating a portion of a peripheral region NA of the display panel 1000b1.

FIG. 6B is a schematic plan view for explaining an example of a defect correction method for the display panel 1000b1, and is a plan view schematically illustrating a portion of the peripheral region NA of the display panel 1000b1.

FIG. 7A is a schematic plan view of a display panel 1000c according to a third embodiment of the disclosure, and is a plan view schematically illustrating a portion of a peripheral region NA of the display panel 1000c.

FIG. 7B is a schematic cross-sectional view for explaining a dummy capacitance portion CA of the display panel 1000c.

FIG. 7C is a schematic plan view for explaining an example of a defect correction method for the display panel 1000c, and is a plan view schematically illustrating a portion of the peripheral region NA of the display panel 1000c.

FIG. 7D is a schematic cross-sectional view of a dummy capacitance portion CA of the display panel 1000c for explaining an example of a defect correction method for the display panel 1000c.

### DESCRIPTION OF EMBODIMENTS

Hereinafter, embodiments of the disclosure will be described with reference to the accompanying drawings. Note that, although a liquid crystal display panel will be described below as an example of a display panel according to an embodiment of the disclosure, the disclosure is not limited to the following embodiment and can be applied to an active matrix display panel of an organic electroluminescent (EL) display device, for example. In the following drawings, constituent elements having substantially the same functions may be denoted by common reference signs, and description thereof may be omitted.

### First Embodiment

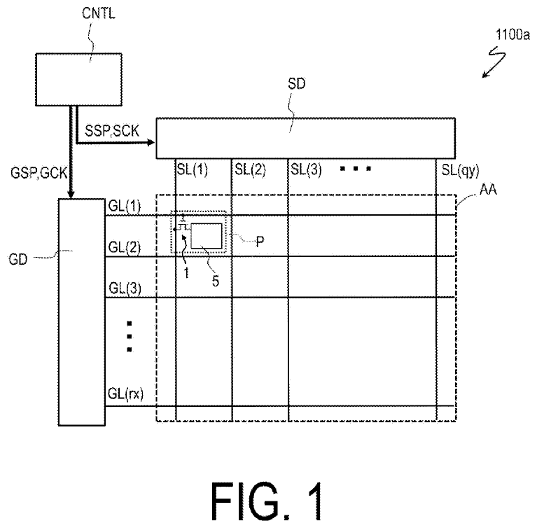

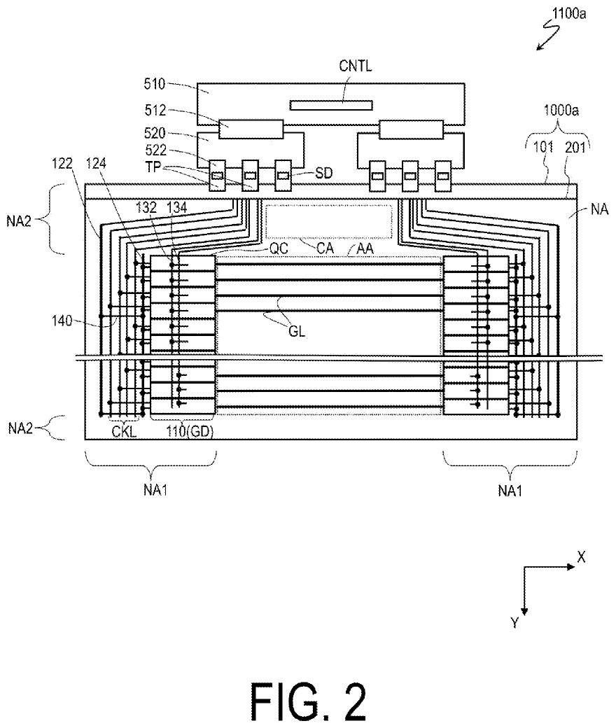

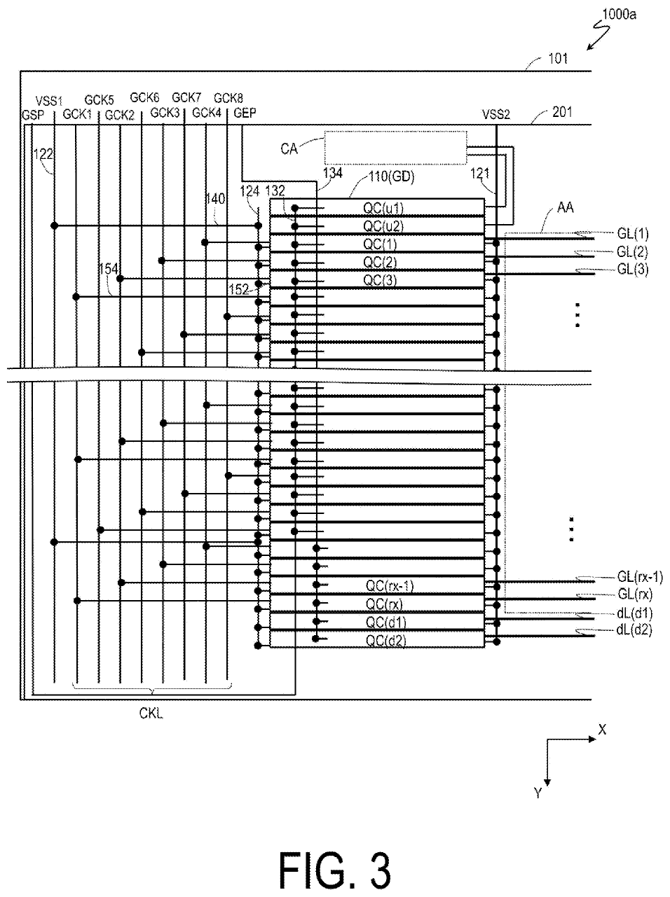

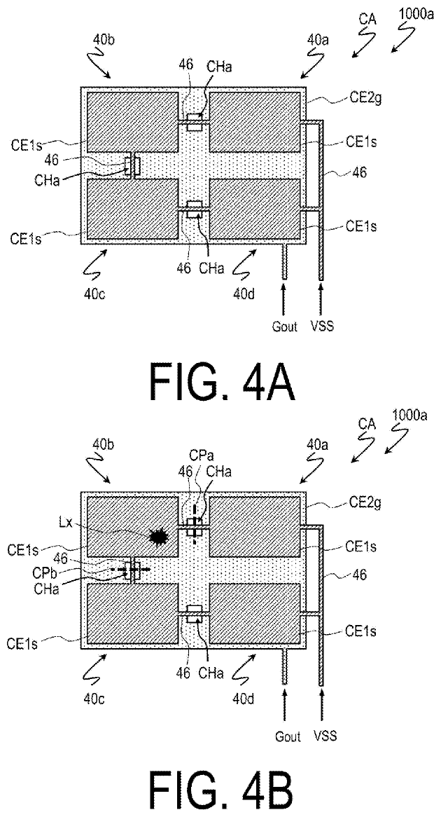

A liquid crystal display panel 1000a and a liquid crystal display device 1100a including the liquid crystal display panel 1000a (hereinafter also referred to as “display panel 1000a” and “display device 1100a”) according to the present embodiment will be described with reference to FIGS. 1, 2, 3, and 4A. FIG. 1 is a schematic view illustrating a configuration of the display device 1100a. FIG. 2 is a schematic plan view of the display device 1100a. FIG. 3 is a schematic plan view illustrating a portion of the display panel 1000a. FIG. 4A is a schematic plan view illustrating a portion of a peripheral region NA of the display panel 1000a.

As illustrated in FIGS. 1 and 2, the display panel 1000a includes a plurality of pixels P arrayed in a matrix shape including a plurality of pixel rows and a plurality of pixel columns. Each pixel P is provided with a thin film transistor (TFT) 1 and a pixel electrode 5 electrically connected to the TFT 1. The pixel row is a plurality of the pixels P arrayed in a row direction (X direction in FIG. 2), and the pixel column is a plurality of the pixels P arrayed in a column direction (Y direction in FIG. 2). The display panel 1000a includes a TFT substrate 101 and a counter substrate 201 facing each other, and a liquid crystal layer provided between these substrates. The display panel 1000a includes a display region AA defined by the plurality of pixels P, and the peripheral region NA other than the display region AA. The peripheral region NA includes a first peripheral region NA1 outward of the display region AA in the row direction, and a second peripheral region NA2 outward of the display region AA in the column direction. The display device 1100a includes the display panel 1000a and a circuit substrate 510 connected to the display panel 1000a.

In this example, a gate bus line GL is associated with each of the plurality of pixel rows, and a source bus line SL is associated with each of the plurality of pixel columns. The TFT 1 of each pixel P is supplied with a gate signal from the corresponding gate bus line GL, and is supplied with a source signal from the corresponding source bus line SL. The pixel rows may be referred to as a first row, a second row, . . . , and an rx-th row in order from the top, and the gate bus line associated with the r-th pixel row (1≤r≤rx) may be referred to as a gate bus line GL (r) (see FIG. 1). Here, rx is the number of pixel rows included in the display panel 1000a. The pixel in the r-th pixel row is selected by the scanning signal voltage supplied to the gate bus line GL (r). The gate bus line GL (r) associated with the r-th pixel row is connected to a gate electrode of the TFTs connected to the pixels included in the r-th pixel row. The pixel columns may be referred to as a first column, a second column, . . . , and a qy-th column in order from the left, and the source bus line SL associated with the q-th pixel column may be referred to as a source bus line SL (q). Here, qy is the number of pixel columns included in the display panel 1000a. A display signal voltage is supplied from the source bus line SL (q) to the pixels in the q-th pixel column (1≤q≤qy). The source bus line SL (q) associated with the q-th pixel column is connected to a source electrode of the TFTs connected to the pixels included in the q-th pixel column.

The display panel 1000a includes a gate drive circuit GD. Herein, the gate drive circuit GD is integrally formed on the TFT substrate 101 (gate driver monolithic). The gate drive circuit GD is provided in the first peripheral region NA1 of the display panel 1000a and includes a shift register 110 including a plurality of stages (also referred to as “drive stages”) respectively associated with the plurality of pixel rows. Outputs of each drive stage of the shift register 110 are connected to the gate bus lines GL respectively associated with the plurality of pixel rows. Typically, the shift register 110 includes rx drive stages and, given that the first stage, the second stage, . . . , and the rx-th stage are arranged in this order from the top, the output of the r-th stage (1≤r≤rx) is connected to the gate bus line GL (r). In addition to the rx drive stages, the shift register 110 further includes one or a plurality of dummy stages adjacent to the rx drive stages in the column direction and not contributing to display. In this example, a plurality of the dummy stages are provided on both upper and lower sides of the rx drive stages. The dummy stages provided on the upper side of the drive stages (that is, the stage before the first stage of the drive stages) are referred to as a u1 stage and a u2 stage in this order from the top, and the dummy stages provided on the lower side of the drive stages (that is, the stage after the last stage of the drive stages) are referred to as a d1 stage and a d2 stage in this order from the top. The shift register 110 is configured by cascade-connecting a plurality of unit circuits QC. Each stage (each drive stage and dummy stage) of the shift register 110 is configured by each unit circuit QC. The unit circuit QC constituting each stage of the shift register 110 includes at least one TFT. The drive stage of the r-th stage (1≤r≤rx) is constituted by the unit circuit QC (r), and the dummy stages of the u1 stage, the u2 stage, the d1 stage, and the d2 stage are constituted by the unit circuits QC (u1), QC (u2), QC (d1), QC (d2), respectively. The number of dummy stages included in the shift register 110 is not limited to the illustrated example, and may be changed as appropriate to a form in which at least one dummy stage is provided on the upper side of the drive stages (a stage before the first stage of the drive stages) and/or on the lower side of the drive stages (a stage after the last stage of the drive stages).

A plurality of capacitance elements 40 connected in parallel and included in a dummy capacitance portion CA provided in the peripheral region NA are respectively connected to, among the dummy stages of the shift register 110, the dummy stages provided on the upper side of the drive stages. Further, herein, a dummy bus line dL is connected to, among the dummy stages of the shift register 110, each of the dummy stages provided on the lower side of the drive stages. The dummy bus line dL has, for example, a wiring line resistance equivalent to that of the gate bus line GL. By connecting the dummy capacitance portion CA or the dummy bus line dL to each of the dummy stages, a capacitance equivalent to a parasitic capacitance formed by the gate bus line GL is connected to each of the dummy stages. A load of the unit circuit QC of the dummy stage is designed to be substantially equal to a load of the unit circuit QC of the drive stage. The load of the unit circuit QC of each stage of the shift register 110 is determined by the capacitance and the resistance of the wiring line connected to the unit circuit QC.

As illustrated in FIG. 4A, the dummy capacitance portion CA includes four capacitance elements 40a, 40b, 40c, and 40d (which may be collectively referred to as “capacitance elements 40”) connected in parallel. Herein, the four capacitance elements 40a to 40d each include a first capacitance electrode CE1s, a second capacitance electrode CE2g, and a dielectric layer positioned between the first capacitance electrode CE1s and the second capacitance electrode CE2g. The same potentials are supplied to the first capacitance electrodes CE1s of the four capacitance elements 40, and the same potentials are supplied to the second capacitance electrodes CE2g of the four capacitance elements 40. Potentials different from each other are supplied to the first capacitance electrodes CE1s and the second capacitance electrodes CE2g. A signal for applying a low-level potential VSS is supplied to the first capacitance electrodes CE1s. For example, a scanning signal Gout supplied to the gate bus lines GL is supplied to the second capacitance electrodes CE2g.

The dummy capacitance portion CA further includes a plurality of first connection portions 46 (herein, four first connection portions 46). Two ends of each first connection portion 46 are respectively connected to the first capacitance electrode CE1s of any one of the four capacitance elements 40 and to the first capacitance electrode CE1s of any other one of the four capacitance elements 40. Herein, the two ends of each first connection portion 46 are respectively connected to the first capacitance electrodes CE1s of two adjacent capacitance elements 40. The first capacitance electrodes CE1s and the first connection portions 46 are formed of, for example, the same conductive film as that of the source bus line SL (that is, are included in the source metal layer). The second capacitance electrode CE2g is provided in common to the plurality of capacitance elements 40. For example, the second capacitance electrode CE2g at least partially overlaps each of the first capacitance electrodes CE1s of the plurality of capacitance elements 40. The second capacitance electrode CE2g includes a plurality of openings CHa (herein, three openings CHa) each of which overlaps any one of the four first connection portions 46 when viewed from a normal direction of the display panel 1000a (FIG. 4A). Among the four first connection portions 46, the first connection portion 46 with two ends respectively connected to the first capacitance electrode CE1s of the capacitance element 40a and the first capacitance electrode CE1s of the capacitance elements 40d includes a portion not overlapping the second capacitance electrode CE2g, and thus does not need to be provided with an opening in the portion overlapping the second capacitance electrode CE2g. The second capacitance electrode CE2g is formed of, for example, the same conductive film as that of the gate bus line GL (that is, is included in the gate metal layer). Preferably the first connection portion 46 has a shape easily cut by, for example, laser irradiation. Preferably, the first capacitance electrode CE1s of each capacitance element 40 and the second capacitance electrode CE2g at least partially overlap. When the display panel 1000a (or the TFT substrate 101) is viewed from the normal direction, the first connection portions 46 have, for example, an area smaller than that of the first capacitance electrode CE2g provided for forming capacitance with the second capacitance electrodes CE1s. The first connection portions 46 are, for example, portions extending from the first capacitance electrodes CE1s having a substantially rectangular shape, and can also be referred to as portions protruding from outer edges of the first capacitance electrodes CE1s having a substantially rectangular shape. The first connection portion 46 is provided in, for example, a wiring line shape, in other words, is a thin line connecting two of the first capacitance electrodes CE1s, and has a small width with respect to a length of the line. For example, the two ends of the first connection portion 46 are on the outer edges of two of the first capacitance electrodes CE1s.

A defect correction method for the display panel 1000a will now be described with reference to FIG. 4B. When a dielectric breakdown Lx occurs in one capacitance element 40b of the plurality of (herein, four) capacitance elements 40 connected in parallel, the first connection portion 46 with one end connected to the first capacitance electrode CE1s of the capacitance element 40b where the dielectric breakdown occurred is disconnected. Typically, all first connection portions 46 with one end connected to the first capacitance electrode CE1s of the capacitance element 40b where the dielectric breakdown occurred are disconnected. Specifically, for example, as illustrated in FIG. 4B, the first connection portion 46 with two ends respectively connected to the first capacitance electrode CE1s of the capacitance element 40b where the dielectric breakdown occurred and to the first capacitance electrode CE1s of another capacitance element 40a is disconnected (cut point CPa), and the first connection portion 46 with two ends respectively connected to the first capacitance electrode CE1s of the capacitance element 40b where the dielectric breakdown occurred and to the first capacitance electrode CE1s of another capacitance element 40c is disconnected (cut point CPb). The first connection portions 46 are cut at the cut points CPa and CPb by, for example, irradiation with laser light. At this time, with the portions of the first connection portions 46 overlapping the openings CHa of the second capacitance electrode CE2g being cut, the influence on the second capacitance electrode CE2g is suppressed. Accordingly, when a dielectric breakdown occurs in any one of the capacitance elements 40 in the manufacturing process of the display panel 1000a, it is possible to correct the defect of the display panel 1000a by electrically isolating the first capacitance electrode CE1s of the capacitance element 40b where the dielectric breakdown occurred from the first capacitance electrodes CE1s of the other capacitance elements 40a, 40c, 40d. When the display panel 1000a and the defect correction method for the display panel 1000a are used, a decrease in the manufacturing yield of the display panel 1000a is suppressed. A dielectric breakdown of the capacitance element 40 includes, for example, a case in which a short-circuit (leakage) occurs between the first capacitance electrode CE1s and the second capacitance electrode CE2g due to mixing of foreign matters or a formation defect of an insulating film (dielectric layer), and electrostatic breakdown due to electrostatic discharge (ESD) caused by static electricity or the like from the outside.

The display panel 1000a, not requiring provision of a dummy bus line for connection to at least a portion of the dummy stage of the shift register 110 in the peripheral region, can contribute to frame narrowing.

Herein, the source metal layer is disposed on the gate metal layer. That is, the TFT substrate 101 of the display panel 1000a includes a substrate, a gate metal layer supported by the substrate, a dielectric layer (gate insulating layer) covering the gate metal layer, and a source metal layer formed on the dielectric layer. Although an example in which the first capacitance electrodes CE1s and the first connection portions 46 are included in the source metal layer, and the second capacitance electrode CE2g is included in the gate metal layer has been described herein, embodiments of the disclosure are not limited to this example. The first capacitance electrodes CE1s and the first connection portions 46 may be included in the gate metal layer, and the second capacitance electrode CE2g may be included in the source metal layer. In this case, for example, the scanning signal Gout supplied to the gate bus lines GL is supplied to the first capacitance electrodes CE1s and, for example, the signal for supplying the low-level potential VSS is supplied to the second capacitance electrode CE2g. Further, in such a defect correction method for a display panel, the portions of the first connection portions 46 (gate metal layer) overlapping the openings CHa of the second capacitance electrode CE2g (source metal layer) can be disconnected from above the gate insulating layer. From the viewpoint of reducing manufacturing costs, preferably the first capacitance electrodes CE1s are included in one of the gate metal layer and the source metal layer, and the second capacitance electrode CE2g is included in the other of the gate metal layer and the source metal layer.

Structures of the display panel 1000a and the display device 1100a will now be described in more detail.

As illustrated in FIG. 2, the circuit substrate 510 includes a control circuit CNTL that supplies a control signal to the gate drive circuit GD. For example, the control circuit CNTL is mounted on the circuit substrate 510. The circuit substrate 510 is connected to a terminal portion TP formed in the second peripheral region NA2 of the display panel 1000a via a source substrate 520. The circuit substrate 510 is connected to the source substrate 520 via flexible printed circuits (FPCs) 512. The terminal portion TP is provided with a terminal electrically connected to each trunk line for supplying a signal to the gate drive circuit GD. The circuit substrate 510 supplies, via the source substrate 520, a signal from the terminal portion TP of the display panel 1000a to each trunk line for supplying a signal to the gate drive circuit GD. In this example, the circuit substrate 510 is connected to the display panel 1000a via a plurality of the source substrates 520. Each of the source substrates 520 (printed wiring boards) is connected to the display panel 1000a via a plurality of the flexible circuit boards 522, and source drive circuits SD for supplying a display signal voltage to the source bus lines SL are mounted on the flexible circuit boards 522. Note that, in FIG. 2, the source bus lines SL are not illustrated for ease of understanding. The control circuit CNTL also supplies control signals to the source drive circuits SD, for example. The control signals supplied from the control circuit CNTL to the gate drive circuit GD include, for example, a gate start pulse signal GSP, a gate clock signal GCK, and a gate end pulse signal GEP. The control signals supplied from the control circuit CNTL to the source drive circuits SD include, for example, a source start pulse signal SSP and a source clock signal SCK. Note that the arrangement and connection method of the source drive circuits SD and the control circuit CNTL are not limited to those illustrated in the drawing. Further, although the gate drive circuit GD and the wiring lines for supplying signals to the gate drive circuit GD are provided on both the left and right sides of the display region AA in FIG. 2, the gate drive circuit GD and the wiring lines for supplying signals to the gate drive circuit GD may be provided on only one of the left and right sides of the display region AA.

FIG. 3 illustrates the wiring lines for inputting signals to the shift register 110 in more detail. The display panel 1000a further includes the following wiring lines provided in the first peripheral region NA1 for supplying signals to the gate drive circuit GD. Specifically, the display panel 1000a includes n clock trunk lines CKL1 to CKLn, each extending in the column direction and supplying n types (where n is an integer of 2 or greater) of clock signals having phases different from each other to the plurality of stages of the shift register 110, an outer trunk line 122 and an inner trunk line 124, each extending in the column direction and supplying a common signal to the plurality of stages of the shift register 110, and a plurality of branch wiring lines 140, each electrically connecting the outer trunk line 122 and the inner trunk line 124. The terminal portions TP in the second peripheral region NA2 of the display panel 1000a are provided with terminals (n clock trunk line terminals and n outer trunk line terminals) electrically connected to the n clock trunk lines CKL1 to CKLn and the outer trunk line 122, respectively. The n clock trunk lines CKL1 to CKLn may be collectively referred to as clock trunk lines CKL.

In the example of FIG. 3, eight clock trunk lines CKL1 to CKL8 are provided as the n clock trunk lines CKL1 to CKLn (n=8). Given that the gate clock signals GCK supplied from the clock trunk lines CKL1 to CKL8 are GCK1 to GCK8, the gate clock signals GCK1 to GCK8 are, for example, oscillating voltages having a cycle of 8H (1H is one horizontal scanning period) and a duty ratio of 1:1 (of the 8 Hs of one cycle, 4 Hs are at high level, and 4 Hs are at low level), and the phases differ for each 1H. For example, a low-level potential Vg1 is −7 V and a high-level potential Vgh is 35 V. The terminal portions TP in the second peripheral region NA2 of the display panel 1000a are provided with terminals (eight clock trunk line terminals) electrically connected to the clock trunk lines CKL1 to CKL8, respectively, and the control circuit CNTL respectively supplies the gate clock signals GCK1 to GCK8 to the clock trunk lines CKL1 to CKL8 connected via the clock trunk line terminals. The clock trunk lines CKL1 to CKL8 and the inputs (input terminals) of the stages of the shift register 110 are electrically connected to each other via wiring lines 154 extending in the row direction, and thus the gate clock signals GCK1 to GCK8 are supplied to the inputs of the stages of the shift register 110. An example of a connection relationship between the input of each stage of the shift register 110 and the n clock trunk lines CKL1 to CKLn is as follows. For example, the inputs of the first to eighth stages are supplied with the gate clock signals GCK1 to GCK8 from the clock trunk lines CKL1 to CKL8, respectively, the inputs of the ninth to 16th stages are supplied with the gate clock signals GCK1 to GCK8 from the clock trunk lines CKL1 to CKL8, respectively, the inputs of the 17th to 24th stages are supplied with the gate clock signals GCK1 to GCK8 from the clock trunk lines CKL1 to CKL8, respectively, and so on. That is, the input of the {(a×n)+k}-th stage of the shift register 110 is supplied with the gate clock signal GCKk from the clock trunk line CKLk (where a is an integer of 0 or greater, and k is an integer from 0 to n−1).

The outer trunk line 122 and the inner trunk line 124 are for supplying, for example, a signal for applying a low-level potential (for example, VSS=−7 V) to the plurality of stages of the shift register 110. A signal for applying a fixed potential (for example, a signal for applying the low-level potential VSS) is supplied from the control circuit CNTL to the outer trunk line 122 connected via the outer trunk line terminal. With the outer trunk line 122 and the inner trunk line 124 being electrically connected via the branch wiring lines 140, and the inner trunk line 124 and the input (input terminal) of each stage of the shift register 110 being electrically connected via the wiring line 152, a signal for applying the low-level potential VSS is supplied to the input of each stage of the shift register 110.

The display panel 1000a may further include an additional trunk line 121 provided in the first peripheral region NA1, extending in the column direction, and supplying another common signal to the plurality of stages of the shift register 110. In this case, signals for applying two kinds of low-level potentials (for example, VSS1=−12 V and VSS2=−7 V) are supplied from the control circuit CNTL. The outer trunk line 122 and the inner trunk line 124 supply signals for applying the low-level potential VSS2 to the plurality of stages of the shift register 110, and the trunk line 121 supplies a signal for applying the low-level potential VSS1 to the plurality of stages of the shift register 110.

Note that the outer trunk line 122 and the inner trunk line 124 may be for supplying, for example, a signal VD for applying a high-level potential (which may be different from Vgh) to the plurality of stages of the shift register 110. The signal VD for applying a high-level potential may be supplied from the control circuit CNTL to the outer trunk line 122 connected via the outer trunk line terminal.

In this example, the inner trunk line 124 is disposed farther from the display region AA than the shift register 110, and the outer trunk line 122 is disposed farther from the display region AA than the inner trunk line 124. The eight clock trunk lines CKL1 to CKL8 are provided between the outer trunk line 122 and the inner trunk line 124. A width of the outer trunk line 122 in the row direction is typically larger than a width of the inner trunk line 124 in the row direction.

The display panel 1000a further includes a first trunk line 132 and a second trunk line 134 for supplying signals to each of the plurality of stages of the shift register 110. The first trunk line 132 and the second trunk line 134 are used to supply a clear signal (reset signal) to each stage of the shift register 110, for example. The gate start pulse signal GSP and/or the gate end pulse signal GEP may be used as the clear signal. The first trunk line 132 is provided in the first peripheral region NA1 and supplies a common signal to one or a plurality of first type stages included in the plurality of stages. The second trunk line 134 is provided between the first trunk line 132 and the display region AA, and supplies another common signal to one or a plurality of second type stages included in the plurality of stages. The first trunk line 132 and the second trunk line 134 extend in the column direction. The first trunk line 132 and the second trunk line 134 are electrically independent from each other, making it possible to supply signals different from each other to the first type stages and the second type stages.

### Second Embodiment

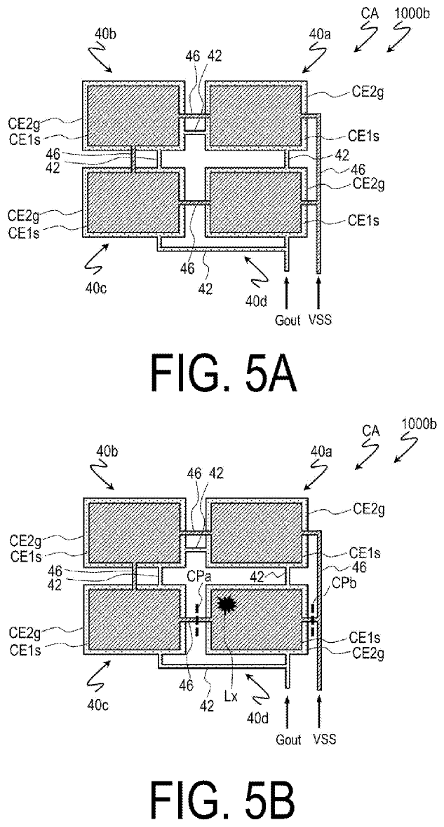

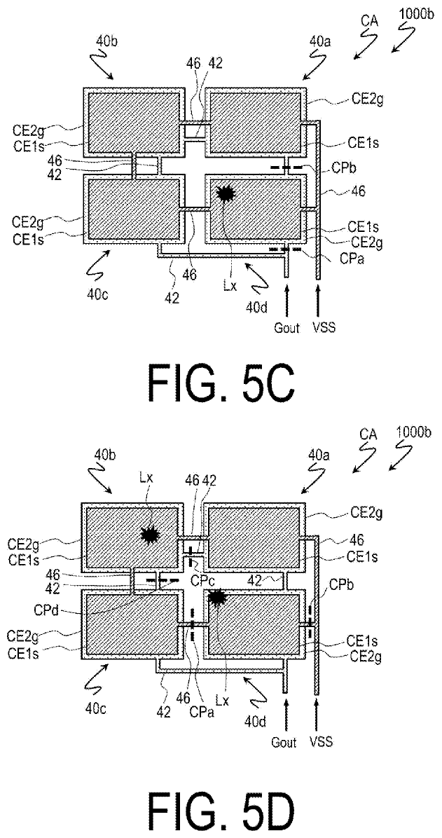

A display panel 1000b and a defect correction method thereof according to the present embodiment will now be described with reference to FIGS. 5A, 5B, 5C, and 5D. FIG. 5A is a schematic plan view of the display panel 1000b, and is a plan view schematically illustrating a portion of the peripheral region NA. FIGS. 5B, 5C, and 5D are schematic plan views for explaining the defect correction method for the display panel 1000b. The following mainly describes differences from the previous embodiment.

In the display panel 1000a, the second capacitance electrode CE2g is provided in common to the plurality of capacitance elements 40, but in the display panel 1000b, four second capacitance electrodes CE2g are provided correspondingly to the four capacitance elements 40. In the display panel 1000b, the dummy capacitance portion CA further includes a plurality of second connection portions 42 (herein, four second connection portions 42). Two ends of each second connection portion 42 are respectively connected to the second capacitance electrode CE2g of any one of the four capacitance elements 40 and to the second capacitance electrode CE2g of any other one of the four capacitance elements 40. Here, the two ends of each second connection portion 42 are connected to the second capacitance electrodes CE2g of two adjacent capacitance elements 40. Each of the second connection portions 42 does not overlap any of the first connection portions 46 when viewed from a normal direction of the display panel 1000b (FIG. 5A). A shape of the second connection portions 42 and a relationship between the second connection portions 42 and the second capacitance electrodes CE2g are the same as those of the first connection portions 46 and the first capacitance electrodes CE1s.

An example of the defect correction method for the display panel 1000b will now be described with reference to FIGS. 5B and 5C. When the dielectric breakdown Lx occurs in one capacitance element 40d of the plurality of capacitance elements 40 connected in parallel, the defect can be corrected by disconnecting the first connection portion 46 with one end connected to the first capacitance electrode CE1s of the capacitance element 40d where the dielectric breakdown occurred, or by disconnecting the second connection portion 42 with one end connected to the second capacitance electrode CE2g of the capacitance element 40d where the dielectric breakdown occurred. Typically, all first connection portions 46 with one end connected to the first capacitance electrode CE1s of the capacitance element 40d where the dielectric breakdown occurred are disconnected, or all second connection portions 42 with one end connected to the second capacitance electrode CE2g of the capacitance element 40d where the dielectric breakdown occurred are disconnected. Specifically, for example, as illustrated in FIG. 5B, the first connection portion 46 with two ends respectively connected to the first capacitance electrode CE1s of the capacitance element 40d where the dielectric breakdown occurred and to the first capacitance electrode CE1s of another capacitance element 40c is disconnected (cut point CPa), and the first connection portion 46 with two ends respectively connected to the first capacitance electrode CE1s of the capacitance element 40d where the dielectric breakdown occurred and to the first capacitance electrode CE1s of another capacitance element 40a is disconnected (cut point CPb). Alternatively, as illustrated in FIG. 5C, the second connection portion 42 with two ends respectively connected to the second capacitance electrode CE2g of the capacitance element 40d where the dielectric breakdown occurred and to the second capacitance electrode CE2g of another capacitance element 40c is disconnected (cut point CPa), and the second connection portion 42 with two ends respectively connected to the second capacitance electrode CE2g of the capacitance element 40d where the dielectric breakdown occurred and to the second capacitance electrode CE2g of another capacitance element 40a is disconnected (cut point CPb). The defect of the display panel 1000b can be corrected by either of the defect correction methods of FIG. 5B and FIG. 5C. The display panel 1000b can suppress a decrease in manufacturing yield. Further, with the display panel 1000b, it is possible to select whether to disconnect the first connection portion 46 as in the defect correction method of FIG. 5B or disconnect the second connection portion 42 as in the defect correction method of FIG. 5C. The display panel 1000b can suppress a decrease in manufacturing yield more than the display panel 1000a.

Another example of the defect correction method for the display panel 1000b will be described with reference to FIG. 5D. The display panel 1000b can correct a defect even when a dielectric breakdown occurs in two capacitance elements 40 of the plurality of capacitance elements 40, making it possible to more effectively suppress a decrease in manufacturing yield than with the display panel 1000a. When a dielectric breakdown occurs in any two (herein, capacitance elements 40d and 40b) of the plurality of capacitance elements 40 connected in parallel, the first connection portions 46 with one end connected to the first capacitance electrode CE1s of one of the two capacitance elements 40 where the dielectric breakdown occurs are (typically all) disconnected, and the second connection portions 42 with one end connected to the second capacitance electrode CE2g of the other of the two capacitance elements where the dielectric breakdown occurred are (typically all) disconnected. Specifically, for example, the following four locations are disconnected.
The first connection portion 46 with two ends respectively connected to the first capacitance electrode CE1s of one capacitance element 40d of the two capacitance elements where the dielectric breakdown occurred and to the first capacitance electrode CE1s of any one capacitance element 40c of the four capacitance elements 40 other than the two capacitance elements where the dielectric breakdown occurred is disconnected (cut point CPa).
The first connection portion 46 with two ends respectively connected to the first capacitance electrode CE1s of one capacitance element 40d of the two capacitance elements where the dielectric breakdown occurred and to the first capacitance electrode CE1s of any other one capacitance element 40a of the four capacitance elements 40 other than the two capacitance elements where the dielectric breakdown occurred is disconnected (cut point CPb).
The second connection portion 42 with two ends respectively connected to the second capacitance electrode CE2g of the other capacitance element 40b of the two capacitance elements where the dielectric breakdown occurred and to the second capacitance electrode CE2g of any one capacitance element 40a of the four capacitance elements 40 other than the two capacitance elements where the dielectric breakdown occurred is disconnected (cut point CPc).
The second connection portion 42 with two ends respectively connected to the second capacitance electrode CE2g of the other capacitance element 40b of the two capacitance elements where the dielectric breakdown occurred and to the second capacitance electrode CE2g of any other one capacitance element 40c of the four capacitance elements 40 other than the two capacitance elements where the dielectric breakdown occurred is disconnected (cut point CPd).

The display panel 1000b satisfies (1) and (2) below, making it possible to correct a defect when a dielectric breakdown occurs in any two capacitance elements 40 of the plurality of (herein, four) capacitance elements 40.

(1) For each of the four first capacitance electrodes CE1s, there are two or more electrically conductive paths each extending from an input end (tip of an arrow of “VSS” in the drawing), which is configured to input a signal for applying a potential to the first capacitance electrode CE1s, to each of the four first capacitance electrodes CE1s. Here, the “path” can also include other first capacitance electrodes CE1s in addition to the one or plurality of first connection portions 46.

(2) For each of the four second capacitance electrodes CE2g, there are two or more electrically conductive paths each extending from an input end (tip of an arrow of “Gout” in the drawing), which is configured to input a signal for applying a potential to the second capacitance electrode CE2g, to each of the four second capacitance electrodes CE2g. Here, the “path” can include other second capacitance electrodes CE2g in addition to the one or plurality of second connection portions 42.

Preferably, both (1) and (2) described above are satisfied, but only one may be satisfied. To satisfy (1) described above, preferably (3a) and (3b) below are satisfied and, to satisfy (2) described above, preferably (4a) and (4b) below are satisfied.

(3a) The first capacitance electrode CE1s of each of the four capacitance elements 40 is connected to one end of each of any two or more of the four first connection portions 46, and the other end of each of the any two or more of the four first connection portions 46 is connected to the first capacitance electrode CE1s of a different capacitance element among the four capacitance elements 40. In other words, the first capacitance electrode CE1s of each of the four capacitance elements 40 is connected to one end of two or more first connection portions 46, and the other ends of the two or more first connection portions 46 are connected to the first capacitance electrodes CE1s of the capacitance elements 40 different from each other.

(3b) The four capacitance elements 40 include two or more capacitance elements each including the first capacitance electrode CE1s connected to an input end (tip of an arrow of “VSS” in the drawing) without passing through the first capacitance electrode CE1s of another capacitance element, the input end being configured to input a signal for applying a potential to the first capacitance electrode CE1s. In the examples of FIGS. 5A to 5D, the capacitance elements 40a and 40d are each connected to an input end that inputs a signal for applying a potential to the first capacitance electrode CE1s without passing through another capacitance element.

(4a) The second capacitance electrode CE2g of each of the four capacitance elements 40 is connected to one end of each of any two or more of the four second connection portions 42, and the other end of each of the any two or more of the four second connection portions 42 is connected to the second capacitance electrode CE2g of a different capacitance element among the four capacitance elements 40. In other words, the second capacitance electrode CE2g of each of the four capacitance elements 40 is connected to one end of two or more second connection portions 42, and the other ends of the two or more second connection portions 42 are connected to the second capacitance electrodes CE2g of the capacitance elements 40 different from each other.

(4b) The four capacitance elements 40 include two or more capacitance elements each including the second capacitance electrode CE2g connected to an input end (tip of an arrow of “Gout” in the drawing) without passing through the second capacitance electrode CE2g of another capacitance element, the input end being configured to input a signal for applying a potential to the second capacitance electrode CE2g. In the examples of FIGS. 5A to 5D, the capacitance elements 40c and 40d are each connected to an input end that inputs a signal for applying a potential to the second capacitance electrode CE2g without passing through another capacitance element.

### Modified Example

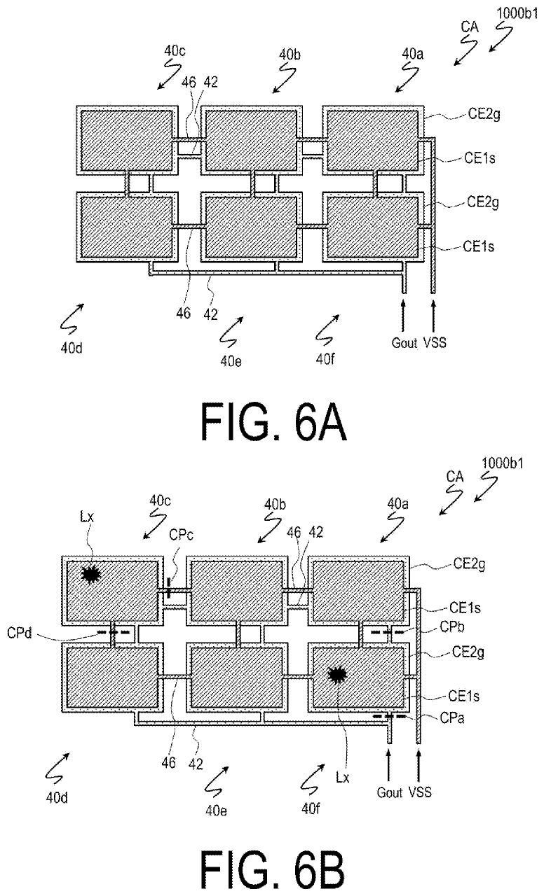

A display panel 1000b1 and a defect correction method thereof according to a modified example of the present embodiment will now be described with reference to FIGS. 6A and 6B. FIG. 6A is a schematic plan view of the display panel 1000b1, and is a plan view schematically illustrating a portion of the peripheral region NA. FIG. 6B is a schematic plan view for explaining the defect correction method for the display panel 1000b1.

The display panel 1000b1 differs from the display panel 1000b in including six capacitance elements 40 connected in parallel in the dummy capacitance portion CA. The display panel 1000b1 satisfies both (1) and (2) described above, making it possible to correct a defect when a dielectric breakdown occurs in any two capacitance elements 40 of the six capacitance elements 40 using a method similar to the defect correction method described with reference to FIGS. 5A and 5B. The same can be said even if the number of capacitance elements 40 connected in parallel and included in the dummy capacitance portion CA is five or seven or more. Specifically, for example, the following four locations are disconnected, as illustrated in FIG. 6B.
The first connection portion 46 with two ends respectively connected to the first capacitance electrode CE1s of one capacitance element 40c of the two capacitance elements 40c and 40f where the dielectric breakdown occurred and to the first capacitance electrode CE1s of any one capacitance element 40b of the four capacitance elements 40 other than the two capacitance elements where the dielectric breakdown occurred is disconnected (cut point CPc).
The first connection portion 46 with two ends respectively connected to the first capacitance electrode CE1s of one capacitance element 40c of the two capacitance elements 40c and 40f where the dielectric breakdown occurred and to the first capacitance electrode CE1s of any other one capacitance element 40d of the four capacitance elements 40 other than the two capacitance elements where the dielectric breakdown occurred is disconnected (cut point CPd).
The second connection portion 42 with two ends respectively connected to the second capacitance electrode CE2g of the other capacitance element 40f of the two capacitance elements 40c and 40f where the dielectric breakdown occurred and to the second capacitance electrode CE2g of any one capacitance element 40e of the four capacitance elements 40 other than the two capacitance elements where the dielectric breakdown occurred is disconnected (cut point CPa)
The second connection portion 42 with two ends respectively connected to the second capacitance electrode CE2g of the other capacitance element 40f of the two capacitance elements 40c and 40f where the dielectric breakdown occurred and to the second capacitance electrode CE2g of any other one capacitance element 40a of the four capacitance elements 40 other than the two capacitance elements where the dielectric breakdown occurred is disconnected (cut point CPb).

### Third Embodiment

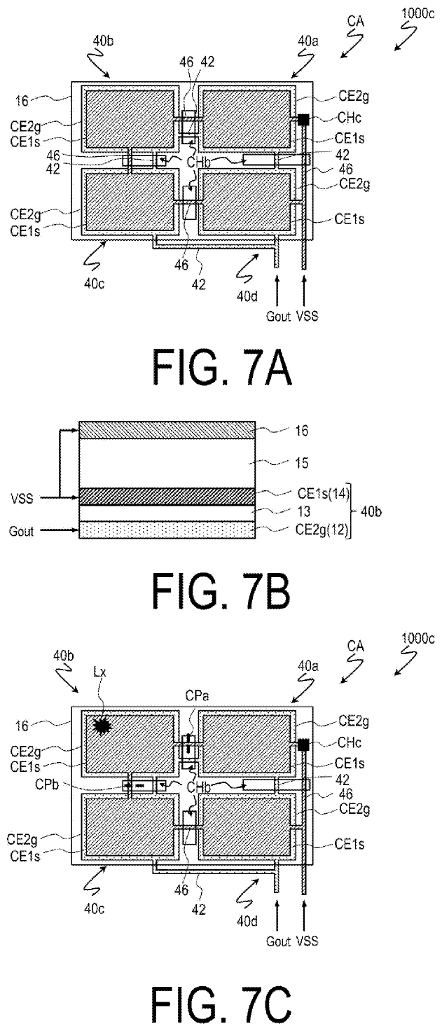

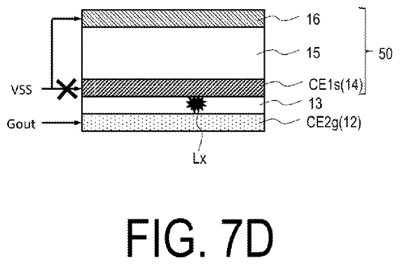

A display panel 1000c and a defect correction method thereof according to the present embodiment will now be described with reference to FIGS. 7A, 7B, 7C, and 7D. FIG. 7A is a schematic plan view of the display panel 1000c, and is a plan view schematically illustrating a portion of the peripheral region NA. FIG. 7B is a schematic cross-sectional view for explaining the dummy capacitance portion CA of the display panel 1000c. FIG. 7C is a schematic plan view for explaining an example of a defect correction method for the display panel 1000c, and is a plan view schematically illustrating a portion of the peripheral region NA of the display panel 1000c. FIG. 7D is a schematic cross-sectional view of the dummy capacitance portion CA of the display panel 1000c for explaining an example of a defect correction method for the display panel 1000c. The following mainly describes differences from the previous embodiment.

The display panel 1000c differs from the display panel 1000b in that the dummy capacitance portion CA further includes an interlayer insulating layer 15 covering the plurality of capacitance elements 40, and a transparent conductive layer 16 formed on the interlayer insulating layer 15. The transparent conductive layer 16 is electrically connected to the first capacitance electrodes CE1s at a contact portion CHc. The transparent conductive layer 16 includes openings CHb overlapping the first connection portions 46 and the second connection portions 42 when viewed from a normal direction of the display panel 1000c (FIG. 7A). The transparent conductive layer 16 is, for example, an indium tin oxide (ITO) layer and is formed of, for example, the same transparent conductive film as that of the pixel electrode 5 provided in each pixel P. The transparent conductive layer 16 is not limited to a conductive layer formed of a transparent conductive material, and may be another conductive layer. As illustrated in FIG. 7B, the transparent conductive layer 16 is provided on the gate metal layer 12 including the second capacitance electrodes CE2g, the source metal layer 14 including the first capacitance electrodes CE1s, and the dielectric layer 13 (for example, gate insulating layer) therebetween, with the interlayer insulating layer 15 interposed between the transparent conductive layer 16 and these layers.

The defect correction method for the display panel 1000c will now be described with reference to FIGS. 7C and 7D. When the dielectric breakdown Lx occurs in one capacitance element 40b of the plurality of capacitance elements 40 connected in parallel, the first connection portion 46 with one end connected to the first capacitance electrode CE1s of the capacitance element 40b where the dielectric breakdown occurred is disconnected. Typically, all first connection portions 46 with one end connected to the first capacitance electrode CE1s of the capacitance element 40b where the dielectric breakdown occurred are disconnected. Specifically, for example, as illustrated in FIG. 7C, the first connection portion 46 with two ends respectively connected to the first capacitance electrode CE1s of the capacitance element 40b where the dielectric breakdown occurred and to the first capacitance electrode CE1s of another capacitance element 40a is disconnected (cut point CPa), and the first connection portion 46 with two ends respectively connected to the first capacitance electrode CE1s of the capacitance element 40b where the dielectric breakdown occurred and to the first capacitance electrode CE1s of another capacitance element 40c is disconnected (cut point CPb). The display panel 1000c can suppress a decrease in manufacturing yield. At this time, in the capacitance element 40b where the dielectric breakdown occurred, the first capacitance electrode CE1s is conductively connected to the second capacitance electrode CE2g. Therefore, after the first connection portion 46 is disconnected, the potential of the first capacitance electrode CE1s of the capacitance element 40b becomes equal to the potential (for example, Gout) of the second capacitance electrode CE2g. On the other hand, the transparent conductive layer 16 is electrically connected to the first capacitance electrodes CE1s. Therefore, the potential of the transparent conductive layer 16 is equal to the potential (for example, VSS) of the first capacitance electrodes CE1s. Accordingly, a capacitance 50 is formed by the first capacitance electrode CE1s of the capacitance element 40b where the dielectric breakdown occurred, the transparent conductive layer 16, and the interlayer insulating layer 15 therebetween. By forming the capacitance 50, it is possible to reduce the influence of separation of the capacitance element 40b where the dielectric breakdown occurred.

Although an example in which the first capacitance electrodes CE1s and the first connection portions 46 are included in the source metal layer and the second capacitance electrodes CE2g are included in the gate metal layer, that is, an example in which the first capacitance electrodes CE1s are disposed on the second capacitance electrodes CE2g, has been described herein, the second capacitance electrodes CE2g may be disposed on the first capacitance electrodes CE1s. In this case, the conductive layer electrically connected to the first capacitance electrodes CE1s faces the first capacitance electrodes CE1s with the insulating layer interposed therebetween, and is positioned on a side of the first capacitance electrodes CE1s opposite to the second capacitance electrodes CE2g. That is, the conductive layer is positioned below the first capacitance electrodes CE1s with the insulating layer interposed therebetween. Even in such a case, the same effects as those of the display panel 1000c can be obtained.

### INDUSTRIAL APPLICABILITY

The display panel according to the embodiments of the disclosure is widely applied to active matrix display panels such as a liquid crystal display panel and an organic EL display panel. When the display panel according to the embodiment of the disclosure is applied, the manufacturing yield of the active matrix display panel can be improved. The defect correction method for a display panel according to an embodiment of the disclosure may be applied to a manufacturing method for a display panel.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A display panel comprising:
a plurality of pixels arrayed in a matrix shape including a plurality of pixel rows and a plurality of pixel columns,
a display region defined by the plurality of pixels;
a peripheral region other than the display region;
a gate drive circuit provided in the peripheral region and including a shift register including a plurality of stages and a dummy stage, the plurality of stages being respectively associated with the plurality of pixel rows; and
a dummy capacitance portion provided in the peripheral region,
wherein the dummy capacitance portion includes a plurality of capacitance elements connected in parallel and connected to the dummy stage,
each of the plurality of capacitance elements includes a first capacitance electrode, a second capacitance electrode, and a dielectric layer positioned between the first capacitance electrode and the second capacitance electrode, and
the dummy capacitance portion further includes at least one first connection portion with two ends respectively connected to the first capacitance electrode of any one of the plurality of capacitance elements and to the first capacitance electrode of any other one of the plurality of capacitance elements.

2. The display panel according to claim 1,
wherein the dummy capacitance portion includes, for each of the first capacitance electrodes of the plurality of capacitance elements, two or more electrically conductive paths each extending from an input end to each of the first capacitance electrodes of the plurality of capacitance elements, the input end being configured to input a signal for applying a potential to the first capacitance electrode.

3. The display panel according to claim 1,
wherein the at least one first connection portion includes a plurality of first connection portions,
the first capacitance electrode of each of the plurality of capacitance elements is connected to one end of each of any two or more of the plurality of first connection portions, and the other end of each of the any two or more of the plurality of first connection portions is connected to the first capacitance electrode of a different capacitance element among the plurality of capacitance elements, and
the plurality of capacitance elements include two or more capacitance elements each including the first capacitance electrode connected to an input end without passing through the first capacitance electrode of any of the plurality of capacitance elements, the input end being configured to input a signal for applying a potential to the first capacitance electrode.

4. The display panel according to claim 1,
wherein the second capacitance electrode is provided in common to the plurality of capacitance elements and includes at least one first opening overlapping the at least one first connection portion.

5. The display panel according to claim 1,
wherein the dummy capacitance portion further includes at least one second connection portion with two ends respectively connected to the second capacitance electrode of any one of the plurality of capacitance elements and to the second capacitance electrode of any other one of the plurality of capacitance elements.

6. The display panel according to claim 5,
wherein the at least one second connection portion does not overlap the at least one first connection portion.

7. The display panel according to claim 5,
wherein the dummy capacitance portion includes, for each of the second capacitance electrodes of the plurality of capacitance elements, two or more electrically conductive paths each extending from an input end to each of the second capacitance electrodes of the plurality of capacitance elements, the input end being configured to input a signal for applying a potential to the second capacitance electrode.

8. The display panel according to claim 5,
wherein the at least one second connection portion includes a plurality of second connection portions,
the second capacitance electrode of each of the plurality of capacitance elements is connected to one end of each of any two or more of the plurality of second connection portions, and the other end of each of the any two or more of the plurality of second connection portions is connected to the second capacitance electrode of a different capacitance element among the plurality of capacitance elements, and
the plurality of capacitance elements include two or more capacitance elements each including the second capacitance electrode connected to an input end without passing through the second capacitance electrode of any of the plurality of capacitance elements, the input end being configured to input a signal for applying a potential to the second capacitance electrode.

9. The display panel according to claim 5,
wherein the dummy capacitance portion further includes a conductive layer facing each of the first capacitance electrodes of the plurality of capacitance elements with an insulating layer interposed therebetween, positioned on a side of the first capacitance electrodes opposite to the second capacitance electrodes, and electrically connected to the first capacitance electrodes, and
the conductive layer includes at least one second opening overlapping the at least one first connection portion and the at least one second connection portion.

10. The display panel according to claim 9,
wherein the conductive layer is formed of a transparent conductive material.

11. The display panel according to claim 9,
wherein the conductive layer is formed of the same conductive film as the pixel electrode provided to each of the plurality of pixels.

12. The display panel according to claim 1,
wherein the first capacitance electrode is supplied with one signal among a signal for applying a low-level potential and a scanning signal for selecting any one of the plurality of pixel rows, and
the second capacitance electrode is supplied with the other signal among the signal for applying a low-level potential and the scanning signal for selecting any one of the plurality of pixel rows.

13. The display panel according to claim 1, comprising
a substrate;
a gate metal layer supported by the substrate;
the dielectric layer covering the gate metal layer; and
a source metal layer formed on the dielectric layer,
wherein each of the first capacitance electrodes is included in one layer among the gate metal layer and the source metal layer, and
each of the second capacitance electrodes is included in the other layer among the gate metal layer and the source metal layer.

14. A defect correction method for the display panel according to claim 1, the defect correction method comprising:
when a dielectric breakdown occurs in any one of the plurality of capacitance elements,
disconnecting the first connection portion connected at one end to the first capacitance electrode of the capacitance element where the dielectric breakdown occurred.

15. A defect correction method for the display panel according to claim 4, the defect correction method comprising:
when a dielectric breakdown occurs in any one of the plurality of capacitance elements,
disconnecting a portion of the first connection portion connected at one end to the first capacitance electrode of the capacitance element where the dielectric breakdown occurred, the portion overlapping the first opening.

16. A defect correction method for the display panel according to claim 5, the defect correction method comprising:
when a dielectric breakdown occurs in any one of the plurality of capacitance elements,
disconnecting the first connection portion connected at one end to the first capacitance electrode of the capacitance element where the dielectric breakdown occurred, or
disconnecting the second connection portion connected at one end to the second capacitance electrode of the capacitance element where the dielectric breakdown occurred.

17. A defect correction method for the display panel according to claim 5, the defect correction method comprising:
when a dielectric breakdown occurs in any two of the plurality of capacitance elements,
disconnecting the first connection portion connected at one end to the first capacitance electrode of one of the two capacitance elements where the dielectric breakdown occurred, and
disconnecting the second connection portion connected at one end to the second capacitance electrode of the other of the two capacitance elements where the dielectric breakdown occurred.

18. A defect correction method for the display panel according to claim 9, the defect correction method comprising:
when a dielectric breakdown occurs in any one of the plurality of capacitance elements,
disconnecting the first connection portion connected at one end to the first capacitance electrode of the capacitance element where the dielectric breakdown occurred.

19. A manufacturing method for a display panel, comprising:
correcting a defect of the display panel by the defect correction method according to claim 14.
